(19) United States
(12) Patent Application Publication
(10) Pub. No.: US 2026/0353731 A1
(43) Pub. Date: Nov. 5, 2026

(54) OXYGEN SCAVENGING SOURCE/DRAIN FOR INTEGRATED DEVICE

(71) Applicant: Taiwan Semiconductor Manufacturing Company, Ltd., Hsinchu (TW)

(72) Inventors: Chih-Yu Chang, New Taipei City (TW); Gao-Ming Wu, Taipei County (TW); Wei-Gang Chiu, New Taipei City (TW); Katherine H. Chiang, New Taipei City (TW)

(21) Appl. No.: 19/740,347

(22) Filed: Jul. 14, 2026

Related U.S. Application Data
(63) Continuation of application No. 18/744,753, filed on Jun. 17, 2024.

(51) Int. Cl. H10D 62/13; H10D 64/23; H10D 64/68; H10P 95/00

(52) U.S. Cl. CPC H10D 62/151; H10D 64/258; H10D 64/691; H10P 95/04

(57) ABSTRACT

Some embodiments relate to an integrated device, including: a semiconductor layer comprising a semiconductor channel; a gate on the semiconductor channel; a first source/drain region on a first side of the semiconductor channel; and a second source/drain region on a second side of the semiconductor channel opposite the first side; where the first source/drain region and the second source/drain region have a first concentration of oxygen vacancies, and the semiconductor channel has a second concentration of oxygen vacancies that is less than the first concentration of oxygen vacancies.

### REFERENCE TO RELATED APPLICATION

This Application is a Continuation of U.S. Application number 18/744,753, filed on Jun. 17, 2024, the contents of which are hereby incorporated by reference in their entirety.

### BACKGROUND

In transistors, a channel separates a first source/drain terminal and a second source/drain terminal. A gate overlies the channel region. To operate the transistor, a voltage is applied to the gate. The voltage, when meeting a device-dependent voltage threshold, induces a conductive channel between the first source/drain terminal and the second source/drain terminal, resulting in the flow of current between the first source/drain terminal and the second source/drain terminal. One factor in determining the voltage threshold of a transistor with an oxide-semiconductor channel is the concentration of oxygen vacancies within the oxide-semiconductor channel.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross-sectional view of some embodiments of a transistor comprising a varying concentration of oxygen vacancies throughout a semiconductor layer.

FIGS. 2A and 2B illustrate cross-sectional and three dimensional views of some embodiments of a transistor comprising a varying concentration of oxygen vacancies throughout a semiconductor layer with a gate stack beneath the semiconductor layer and the first and second source/drain terminals above the semiconductor layer.

FIGS. 3A and 3B illustrate cross-sectional and three-dimensional views of some embodiments of a transistor comprising a varying concentration of oxygen vacancies throughout a semiconductor layer with a gate stack extending between inner sidewalls of the first source/drain terminal towards the second source/drain terminal.

FIGS. 4A and 4B illustrate a cross-sectional view and a three dimensional view of some embodiments of a TRANSISTOR comprising a varying concentration of oxygen vacancies throughout a semiconductor layer with a gate stack extending around outer sidewalls of the first source/drain terminal and the second source/drain terminal.

FIG. 5 illustrates a graph of current densities of transistors utilizing metal terminals with low oxide formation energies compared to transistors utilizing metal terminals with higher oxide formation energies.

FIGS. 6-13 illustrate a series of cross-sectional views of some embodiments of a method of forming a transistor comprising a varying concentration of oxygen vacancies throughout a semiconductor layer with a gate stack beneath the semiconductor layer and the first and second source/drain terminals above the semiconductor layer.

FIGS. 14-20 illustrate a series of cross-sectional views of some embodiments of a method of forming a transistor comprising a varying concentration of oxygen vacancies throughout a semiconductor layer with a gate stack extending between inner sidewalls of the first source/drain terminal towards the second source/drain terminal.

FIGS. 21-26 illustrate a series of cross-sectional views of some embodiments of a method of forming a transistor comprising a varying concentration of oxygen vacancies throughout a semiconductor layer with a gate stack extending around outer sidewalls of the first source/drain terminal and the second source/drain terminal.

FIG. 27 illustrates a flowchart of some embodiments of a method of forming a transistor comprising a varying concentration of oxygen vacancies throughout a semiconductor layer with a gate stack beneath the semiconductor layer and the first and second source/drain terminals above the semiconductor layer.

FIG. 28 illustrates a flowchart of some embodiments of a method of forming a transistor comprising a varying concentration of oxygen vacancies throughout a semiconductor layer with a gate stack extending between inner sidewalls of the first source/drain terminal towards the second source/drain terminal.

FIG. 29 illustrates a flowchart of some embodiments of a method of forming a transistor comprising a varying concentration of oxygen vacancies throughout a semiconductor layer with a gate stack extending around outer sidewalls of the first source/drain terminal and the second source/drain terminal.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A transistor comprises semiconductor layer with a semiconductor channel extending between a first source/drain region and a second source/drain region. A gate stack overlies the semiconductor channel, and comprises a gate terminal and a gate dielectric. A voltage applied to the gate terminal actuates the transistor, switching the operation of the transistor between an “off” mode, and an “on” mode. In the “off” mode, a depletion region (or, in the case of thin film transistors (TFTs), the intrinsic state of the channel) isolates the first source/drain region from the second source/drain region. In the “on” mode, the voltage at the gate terminal attracts mobile charge carriers to the channel, forming a conductive channel between the first source/drain region and the second source/drain region.

The voltage where the inversion channel is formed is known as the threshold voltage of the transistor. The threshold voltage is a metric of a transistor’s performance, with different threshold voltages being applicable in different applications (e.g., a higher threshold voltage may be useable in high-voltage applications, while a lower threshold voltage may be desirable in lower voltage applications, such as those utilizing newer technologies resulting in more compact circuit design). A number of factors determine the threshold voltage of a transistor. One of these factors in designs using an oxide semiconductor channel is the concentration of oxygen vacancies in the semiconductor channel (when an oxide semiconductor is used as the material of the semiconductor channel). A greater number of oxygen vacancies in the semiconductor channel lowers the threshold voltage of the device, reducing the minimum voltage to turn the device on. If the threshold is reduced below the expected noise in the gate voltage, the noise may result in the transistor not actuating according to the applied voltage.

Another metric of a transistor’s performance is the amount of current that is transmitted between the first source/drain region and the second source/drain region when the transistor is in the “on” mode. The current density traveling through a transistor is determined by a number of factors, including the source/drain terminal resistance (e.g., the contact resistance between the metal source/drain terminal and the oxide semiconductor of the source/drain regions). Reducing the source/drain terminal resistance results in an increase in the current density of the transistor. One method of reducing the source/drain terminal resistance is to increase the concentration of oxygen vacancies in the source/drain regions. However, increasing the number of oxygen vacancies within the semiconductor layer may reduce the threshold voltage of the transistor to undesirable levels, and methods of depositing multiple oxide semiconductor layers with different concentrations of oxygen vacancies adds several deposition and patterning steps to the method of forming the transistor, which increases the cost and complexity of the final product. Therefore, a method of increasing the number of oxygen vacancies in the first and second source/drain regions without increasing the concentration of oxygen vacancies in the semiconductor channel is desirable.

The present disclosure describes a transistor with a metal oxide semiconductor channel with a concentration of oxygen vacancies that varies between the source/drain regions and the semiconductor channel. A material with a low oxide formation energy is chosen for the material of the first and second source/drain terminals. The low oxide formation energy results in the formation of an oxide layer between the first and second source/drain terminals and the semiconductor channel during an anneal. The formation of the oxide layer pulls oxygen atoms from the first and second source/drain terminals, resulting in a greater concentration of oxygen vacancies in the first and second source/drain terminals. When a material that forms an oxide with a low resistivity (e.g., less than approximately .5 kΩ-µm) is chosen for the material of the first and second source/drain terminals, the increased concentration of oxygen vacancies and the low resistance of the oxide combined lower the contact resistance of the interface between the first and second source/drain terminals and the first and second source/drain regions. The reduced contact resistance increases the resulting current density of the transistor. The threshold voltage of the transistor is partially based on the concentration of oxygen vacancies in the channel, which is not substantially affected by this technique. Localizing the change in the concentration of oxygen vacancies to the first and second source/drain regions results in changes to the threshold voltage of the transistor being mitigated while increasing the current density of the transistor, improving the overall performance of the device.

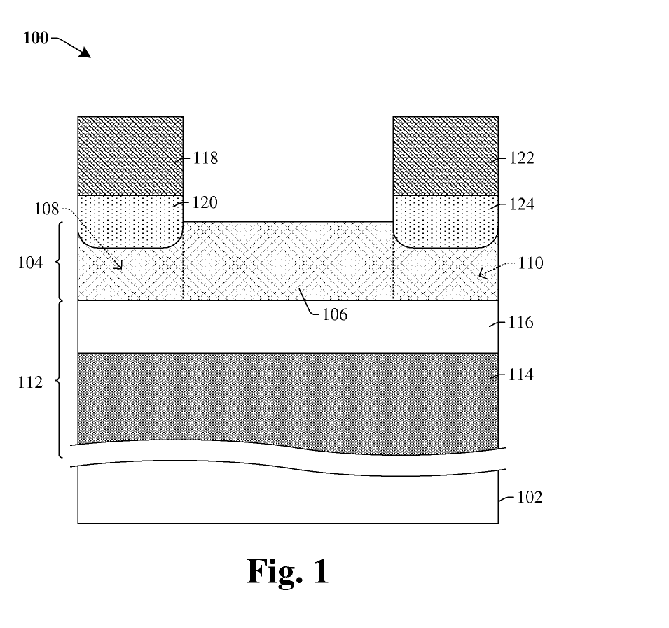

FIG. 1 illustrates a cross-sectional view 100 of some embodiments of a transistor comprising a varying concentration of oxygen vacancies throughout a semiconductor layer.

A semiconductor layer 104 overlies a substrate 102. The semiconductor layer comprises a channel 106, a first source/drain region 108 and a second source/drain region 110. The first source/drain region 108 is on a first side of the channel 106 and the second source/drain region 110 is on a second side of the channel 106 opposite the first side. In some embodiments, a gate stack 112 extends beneath the semiconductor layer 104. The gate stack 112 comprises a gate terminal 114 and a gate dielectric 116. The gate dielectric 116 separates the gate terminal 114 from the semiconductor layer 104.

A first source/drain terminal 118 overlies and is electrically coupled to the first source/drain region 108. A first oxide layer 120 extends between the first source/drain terminal 118 and the first source/drain region 108. Similarly, a second source/drain terminal 122 overlies and is electrically coupled to the second source/drain region 110 through a second oxide layer 124.

The channel 106 has a first concentration of oxygen vacancies, and the first and second source/drain regions 108, 110 have a second concentration of oxygen vacancies that is greater than the first concentration. In some embodiments, the first concentration of oxygen vacancies is less than 40% (e.g., less than 40% of possible oxygen sites in the channel 106 have oxygen vacancies), and the second concentration of oxygen vacancies is greater than 50% (e.g., greater than 50% of possible oxygen sites in the first and second source/drain regions 108, 110 have oxygen vacancies). The greater concentration of oxygen vacancies in the first source/drain region 108 and the second source/drain region 110 reduces the contact resistance between the first and second source/drain regions 108, 110 and the first and second source/drain terminals. The lower concentration of oxygen vacancies throughout the channel 106 results in a higher threshold voltage for the transistor than a semiconductor layer 104 with a uniformly higher concentration of oxygen vacancies would provide. That is, localizing the higher concentration of oxygen vacancies to the first and second source/drain regions 108, 110 increases the current density of the transistor without sacrificing the higher threshold voltage of a transistor with a lower concentration of oxygen vacancies at the channel 106.

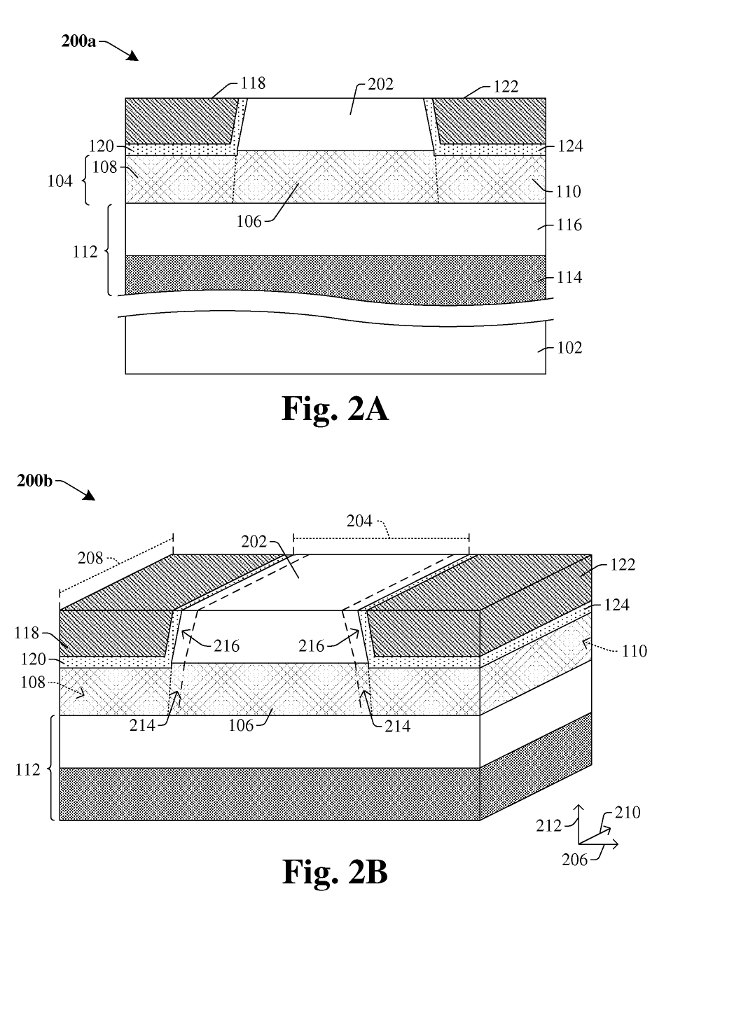

FIGS. 2A and 2B illustrate cross-sectional 200a and three dimensional views 200b of some embodiments of a transistor comprising a varying concentration of oxygen vacancies throughout a semiconductor layer with a gate stack beneath the semiconductor layer and the first and second source/drain terminals above the semiconductor layer.

As shown in the cross-sectional view 200a of FIG. 2A, in some embodiments, an insulative layer 202 extends between the first source/drain terminal 118 and the second source/drain terminal 122. In some embodiments, the insulative layer 202 is or comprises an insulative material such as silicon dioxide (SiO₂) or the like. The oxygen to silicon ratio of the silicon dioxide is greater than or equal to 1.5. In further embodiments, the first and second oxide layers 120, 124 line sidewalls of the first source/drain terminal 118 and the second source/drain terminal 122 at interfaces between the first and second source/drain terminals 118, 122 and the insulative layer 202.

First portions of the first and second oxide layers 120, 124 that are between the first and second source/drain terminals 118, 122 and the semiconductor layer 104 comprise material from both the semiconductor layer 104 and the first or second source/drain terminals 118, 122, respectively. Second portions of the first and second oxide layers 120, 124 that are between the first and second source/drain terminals 118, 122 and the insulative layer 202 comprise material from both the insulative layer 202 and the first or second source/drain terminals 118, 122, respectively.

In some embodiments, the gate stack 112 is positioned directly beneath the semiconductor layer 104 and the first and second source/drain terminals 118, 122. The first and second source/drain terminals 118, 122 are positioned directly above the semiconductor layer 104 and extend over a topmost surface of the semiconductor layer 104. The first source/drain terminal 118 has a topmost surface level with a topmost surface of the second source/drain terminal 122, and has an outer sidewall facing an outer sidewall of the second source/drain terminal 122.

As shown in the three dimensional view 200b of FIG. 2B, in some embodiments, the insulative layer 202 has a first length 204 measured in a first direction 206 between the first source/drain terminal 118 and the second source/drain terminal 122. In some embodiments, the first length 204 is approximately between 25 nanometers and 150 nanometers, between 50 and 200 nanometers, between 25 nanometers and 200 nanometers, or the like. In some embodiments, the first and second source/drain terminals 118, 122 have a first width 208 measured in a second direction 210 perpendicular to the first direction 206. In some embodiments, the first width 208 is approximately between 30 nanometers and 150 nanometers, between 60 and 200 nanometers, between 30 nanometers and 200 nanometers, or the like. The first and second source/drain terminals 118, 122 are separated from the gate stack 112 in a third direction 212 perpendicular to the first direction 206 and the second direction 210.

In some embodiments, the concentration of oxygen vacancies in the first and second source/drain regions 108, 110 is approximately uniform (e.g., with a variation within 10% of the average concentration of oxygen vacancies) throughout a thickness of the first and second source/drain regions 108, 110 measured in the third direction 212. In other embodiments, the concentration of oxygen vacancies in the first and second source/drain regions 108, 110 varies in a gradient, where a greater concentration of oxygen vacancies is at an interface between the first and second oxide layers 120, 124 and the semiconductor layer 104, and a lower concentration of oxygen vacancies is at an interface between the gate stack 112 and the semiconductor layer 104.

In some embodiments, there is an intermediate region 214 surrounding the first and second source/drain regions 108, 110. The intermediate region 214 extends into the channel 106 and has an average concentration of oxygen vacancies between the concentration of oxygen vacancies of the first and second source/drain regions 108, 110 and the concentration of oxygen vacancies of the channel 106. In some embodiments, the concentration of oxygen vacancies in the intermediate region 214 varies as a gradient between the concentration of oxygen vacancies in the first and second source/drain regions 108, 110 and the concentration of oxygen vacancies in the channel 106.

In some embodiments, oxygen vacancy regions 216 surround the sidewalls of the first and second oxide layers 120, 124 in outer regions of the insulative layer 202. The oxygen vacancy regions 216 have a greater concentration of oxygen vacancies than inner regions of the insulative layer 202. In some embodiments, the concentration of oxygen vacancies are distributed in a gradient between a highest concentration of oxygen vacancies near the interface between the first and second oxide layers 120, 124 and a lower concentration of oxygen vacancies at a furthest edge of the oxygen vacancy regions from the interface.

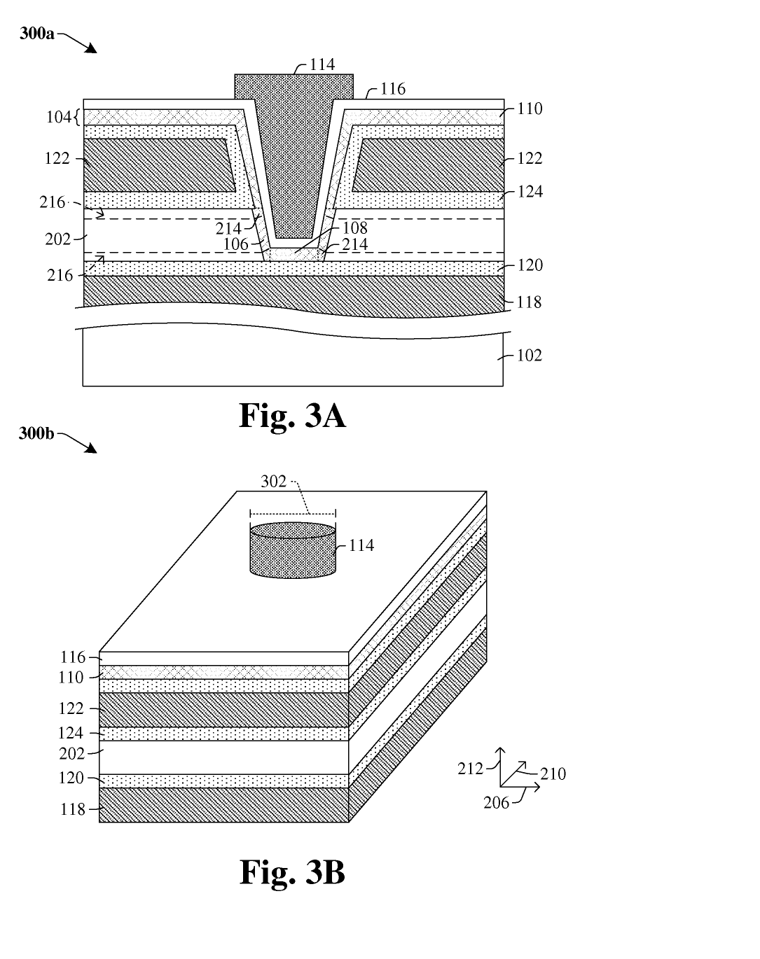

FIGS. 3A and 3B illustrate cross-sectional and three-dimensional views of some embodiments of a transistor comprising a varying concentration of oxygen vacancies throughout a semiconductor layer with a gate stack extending between inner sidewalls of the first source/drain terminal towards the second source/drain terminal.

As shown in the cross-sectional view 300a of FIG. 3A, in some embodiments, the first source/drain terminal 118 extends directly beneath the second source/drain terminal 122. The gate terminal 114 extends through an opening in the second source/drain terminal 122, extending between the first source/drain terminal 118 and the second source/drain terminal 122. The semiconductor layer 104 extends through the opening in the second source/drain terminal 122 as well, such that the first source/drain region 108 is directly beneath a bottommost surface of the gate terminal 114. The second source/drain region 110 surrounds the gate terminal in a continuous ring and extends over an upper surface of the second source/drain terminal 122. The channel 106 extends in a continuous ring between the first source/drain region 108 and the second source/drain region 110. The insulative layer 202 is level with the channel 106, and oxygen vacancy regions 216 line an upper surface and a lower surface of the insulative layer. In some embodiments, the intermediate regions 214 extend between the first and second source/drain regions 108, 110 and the channel 106 in the semiconductor layer 104. The gate dielectric 116 surrounds a lowermost surface of the gate terminal 114 and extends from below the second source/drain terminal 122 to above the second source/drain terminal 122. The first oxide layer 120 covers a top surface of the first source/drain terminal 118, and the second oxide layer 124 covers a top surface, a bottom surface, and an inner sidewall of the second source/drain terminal 122.

As shown in the three dimensional view 300b of FIG. 3B, in some embodiments, the gate terminal 114 has a round profile in a plane aligned with the first direction 206 and the second direction 210. In other embodiments, the gate terminal may have a square profile, a rectangular profile, a hexagonal profile, or the like. The gate terminal 114 extends through the second source/drain terminal 122 in the third direction 212. In some embodiments, the gate terminal 114 has an upper portion that extends above and over an upper surface of the gate dielectric 116, and a lower portion that extends below the upper surface of the gate dielectric 116. In some embodiments, the upper portion of the gate terminal 114 has a diameter 302 between approximately 30 nanometers and 80 nanometers, between approximately 50 nanometers and 100 nanometers, between approximately 30 nanometers and 100 nanometers, or the like.

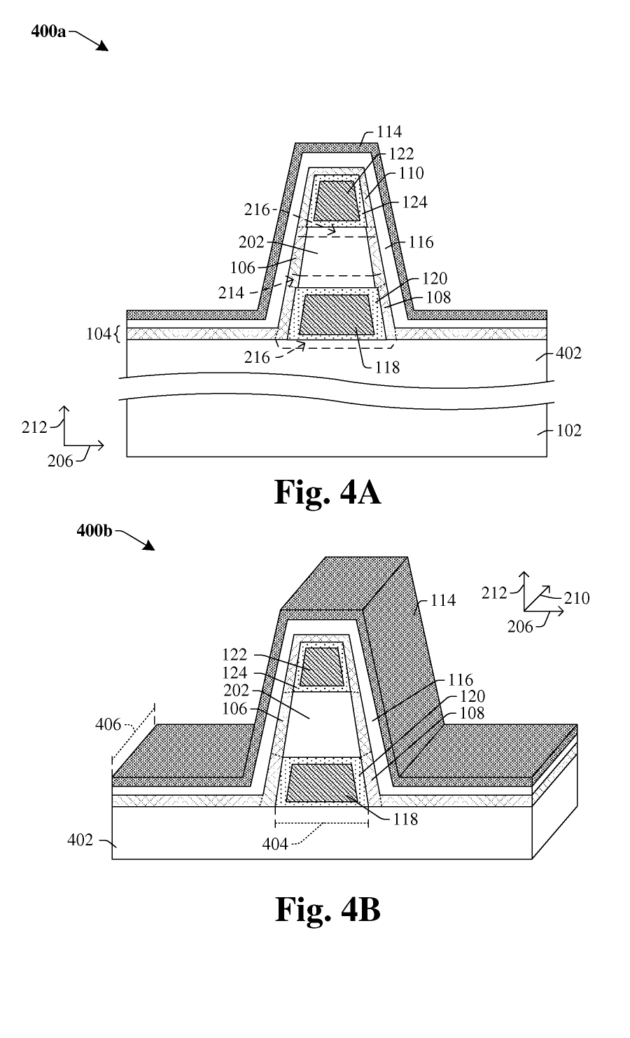

FIGS. 4A and 4B illustrate a cross-sectional view 400a and a three dimensional view 400b of some embodiments of a transistor comprising a varying concentration of oxygen vacancies throughout a semiconductor layer with a gate stack extending around outer sidewalls of the first source/drain terminal and the second source/drain terminal.

As shown in the cross-sectional view of FIG. 4A, in some embodiments, the semiconductor layer 104 and the first source/drain terminal 118 cover an upper surface of a second insulative layer 402. In some embodiments, the second insulative layer 402 comprises a same material as the insulative layer 202. The semiconductor layer 104 extends from a lowermost surface of the first source/drain terminal 118 to above an uppermost surface of the second source/drain terminal 122. The semiconductor layer 104 extends over the first and second source/drain terminals 118, 122 in the third direction 212 and surrounds outer sidewalls of the first and second source/drain terminals 118, 122 in the first direction 206. The insulative layer 202 extends between the first source/drain terminal 118 and the second source/drain terminal 122 in the third direction 212, and the channel 106 lines outer sidewalls of the insulative layer 202. The first source/drain region 108 lines outer sidewalls of the first source/drain terminal 118 in the first direction 206. The second source/drain region 110 lines outer sidewalls and an upper surface of the second source/drain terminal 122. In some embodiments, the first and second oxide layers 120, 124 completely surround the first and second source/drain terminals 118, 122, respectively. The gate terminal 114 extends over and surrounds outer sidewalls of the semiconductor layer 104, and the gate dielectric 116 extends over and surrounds outer sidewalls of the semiconductor layer 104 between the semiconductor layer 104 and the gate terminal 114. Oxygen vacancy regions 216 line upper and lower surfaces of the insulative layer 202 and extend into the second insulative layer 402 beneath the first source/drain terminal 118. In some embodiments, intermediate regions 214 extends between the channel 106 and the first and second source/drain regions 108, 110.

As shown in the three dimensional view 400b of FIG. 4B, in some embodiments, the transistor has a length 406 between approximately 50 and 120 nanometers, between approximately 80 and 150 nanometers, between approximately 50 and 150 nanometers, or the like. In some embodiments, the first source/drain terminal 118 and the first oxide layer 120 have a combined width 404 between approximately 20 nanometers and 80 nanometers, between approximately 40 nanometers and 100 nanometers, between approximately 20 nanometers and 100 nanometers, or the like. In some embodiments, the gate terminal 114 and the gate dielectric 116 extend past outer sidewalls of the first oxide layer 120 in the first direction 206, the second direction 210, and the third direction 212.

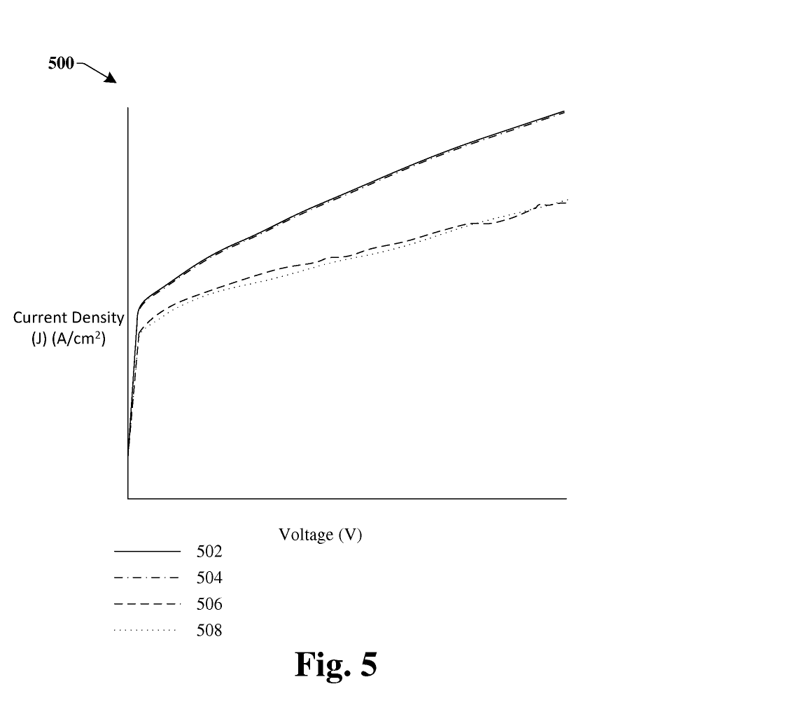

FIG. 5 illustrates a graph 500 of current densities of transistors utilizing metal terminals with low oxide formation energies compared to transistors utilizing metal terminals with higher oxide formation energies.

Graph 500 shows the current densities in relation to voltage of two transistors; a first transistor with first and second source/drain terminals (see 118, 122 of FIG. 1) as described in this disclosure, and a second transistor with third and fourth source/drain terminals comprising titanium nitride (TiN). The first transistor and the second transistor are substantially identical except for the materials of the source/drain terminals and as described below.

The materials of the first and second source/drain terminals (see 118, 122 of FIG. 1) have a lower oxide formation energy (e.g., a lower Gibbs free energy of formation of the metals oxides per mole of O₂) than titanium nitride, resulting in the first and second oxide layers (see 120, 124 of FIG. 1) formed using a first anneal having a greater thickness than a thickness of third and fourth oxide layers of the second transistor formed using an identical anneal to the first anneal. In some embodiments, the thickness of the third and fourth oxide layers after the anneal is approximately 1.4 nanometers, and the thickness of the first and second oxide layers (see 120, 124 of FIG. 1) after the first anneal is approximately 3.7 nanometers. In other embodiments, the third and fourth oxide layers have a different thickness, and the first and second oxide layers (see 120, 124 of FIG. 1) have thicknesses that are approximately 200% to 300% of the thickness of the third or fourth oxide layers. The increased growth rate of the first and second oxide layers (see 120, 124 of FIG. 1) during the first anneal indicates a greater amount of oxygen being sequestered in the first and second oxide layers, and results in the first and second source/drain regions (see 108, 110 of FIG. 1) having a greater concentration of oxygen vacancies than third and fourth source/drain regions of the second transistor.

First line 502 represents the input current density to the first transistor. Line 504 represents the output current density of the first transistor. Line 506 represents the input current density of the second transistor. Line 508 represents the output current density of the second transistor. As shown in the graph 500, the input and output current density of the first transistor exceeds that of the input and output current density of the second transistor. In some embodiments, the difference in current density between the first transistor and the second transistor when in the “on” state is greater than an order of magnitude for gate voltages of less than 1volt. The increased concentration of oxygen vacancies lining the first and second oxide layers (see 120, 124 of FIG. 1) of the first transistor reduces the contact resistance within the first transistor, increasing the current density. It will be appreciated that a substantially similar technique (e.g., utilizing a conductive material with a low oxidation energy in a contact, then annealing to form an oxide layer to increase the concentration of oxygen vacancies in a semiconductor layer near the resulting oxide layer) may be applied to the formation of a Schottky diode, a gate-all-around (GAA) device, or other integrated devices utilizing metal-oxide semiconductor materials and metal terminals to reduce the contact resistance and increase the current density of the previously stated devices.

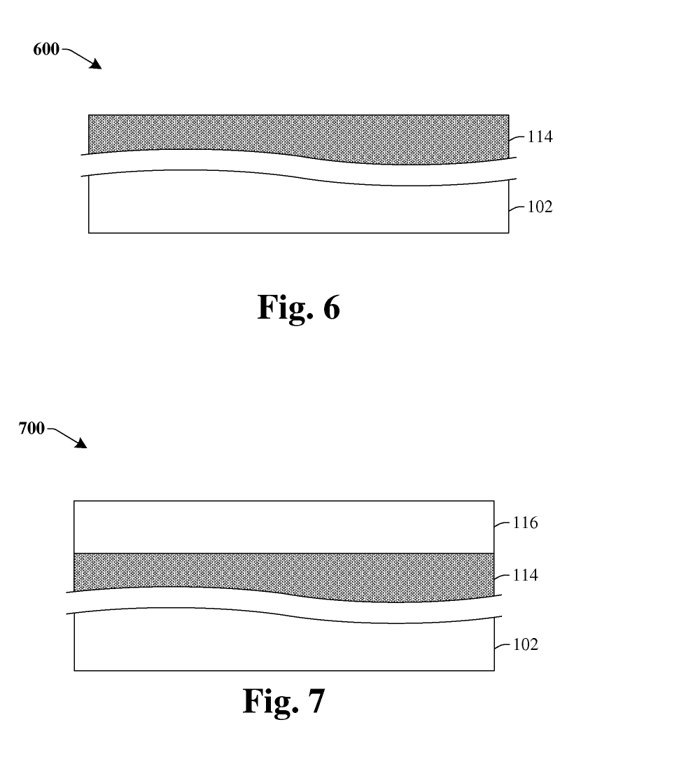

FIGS. 6-13 illustrate a series of cross-sectional views 600-1300 of some embodiments of a method of forming a transistor comprising a varying concentration of oxygen vacancies throughout a semiconductor layer with a gate stack beneath the semiconductor layer and the first and second source/drain terminals above the semiconductor layer. Although FIGS. 6-13 are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part.

As shown in the cross-sectional view 600 of FIG. 6, the gate terminal 114 is formed over a substrate 102. In some embodiments, the gate terminal 114 is or comprises a conductive material, such as titanium nitride (TiN), tantalum nitride (TaN), tungsten (W), tungsten nitride (WN), or the like. In some embodiments, the gate terminal 114 is formed on and coupled to an interconnect structure formed during in a back end of line (BEOL) process. The gate terminal 114 is formed using one or more of a physical vapor deposition (PVD), atomic layer deposition (ALD), chemical vapor deposition (CVD), or the like.

As shown in the cross-sectional view 700 of FIG. 7, the gate dielectric 116 is formed over the gate terminal 114. In some embodiments, the gate dielectric 116 is or comprises an insulative material, such as hafnium oxide (HfO₂), aluminum oxide (Al₂O₃), or the like. The gate terminal 114 is formed using one or more of PVD, ALD, CVD, or the like. In some embodiments, the gate dielectric 116 has a thickness between approximately 2 nanometers and 8 nanometers, between approximately 5 nanometers and 10 nanometers, between approximately 2 nanometers and 10 nanometers, or the like.

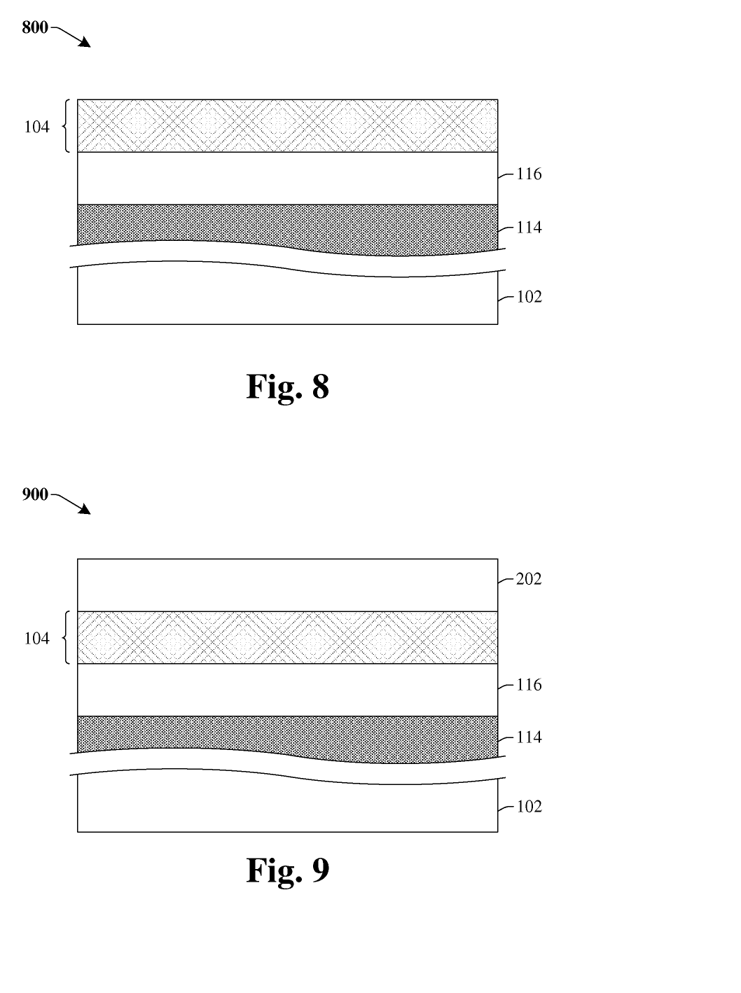

As shown in the cross-sectional view 800 of FIG. 8, the semiconductor layer 104 is formed over the gate dielectric 116. In some embodiments, the semiconductor layer 104 is or comprises an oxide-semiconductor material, such as indium gallium zinc oxide (IGZO), indium tungsten oxide (IWO), indium oxide (In₂O₃), indium tin oxide (ITO), zinc oxide (ZnO), tin oxide (SnO₂), nickel oxide (NiO), copper oxide (Cu₂O), or the like. In some embodiments, the semiconductor layer 104 is an n-type metal oxide semiconductor material. In other embodiments, the semiconductor layer 104 is a p-type metal oxide semiconductor material. In some embodiments, the semiconductor layer 104 has a thickness between approximately 10 nanometers and 50 nanometers, between approximately 20 nanometers and 80 nanometers, between approximately 10 nanometers and 100 nanometers, or the like. The semiconductor layer 104 is formed using one or more of PVD, ALD, CVD, or the like.

As shown in the cross-sectional view 900 of FIG. 9, the insulative layer 202 is formed over the semiconductor layer 104. In some embodiments, the insulative layer 202 is or comprises an insulative material, such as silicon dioxide (SiO₂), or the like. The silicon oxide material of the insulative layer 202 has a ratio of oxygen to silicon of 1.5 or higher. In some embodiments, the insulative layer 202 has a thickness between approximately 10 nanometers and 40 nanometers, between approximately 20 nanometers and 50 nanometers, between approximately 10 nanometers and 50 nanometers, or the like. The semiconductor layer 104 is formed using one or more of a PVD, ALD, CVD, or the like.

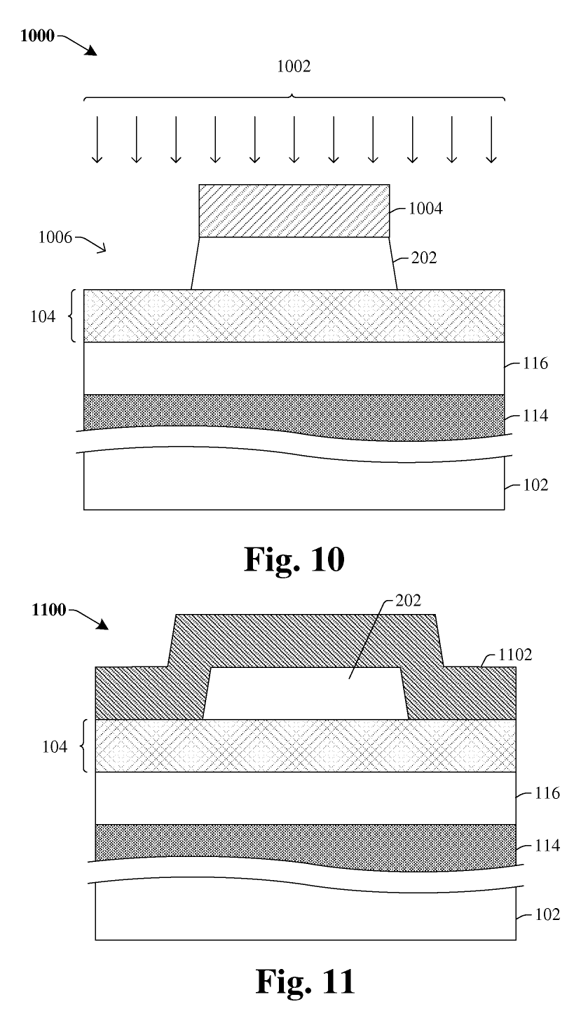

As shown in the cross-sectional view 1000 of FIG. 10, a first masking layer 1004 is formed on the insulative layer 202. In some embodiments, the first masking layer 1004 is or comprises a photoresist and is patterned using photolithography. The first masking layer 1004 is formed using one or more of PVD, ALD, CVD, a spin on process, a dipping process, or the like. After the first masking layer 1004 is formed and patterned, a first etch 1002 is performed on the insulative layer 202. In some embodiments, the first etch 1002 is an anisotropic dry etching process. The first etch 1002 results in openings 1006 being formed in the insulative layer 202 corresponding to the positions of the first and second source/drain terminals (see 118, 122 of FIG. 2A) to be formed hereafter. The first masking layer 1004 is then removed.

As shown in the cross-sectional view 1100 of FIG. 11, a conformal metal layer 1102 is formed over the insulative layer 202. In some embodiments, the conformal metal layer 1102 is or comprises a conductive material, such as tantalum nitride (TaN), tantalum (Ta), titanium (Ti), ruthenium (Ru), a combination of the foregoing, or the like. The conformal metal layer 1102 may additionally be any conductive metal with a low oxide formation energy (e.g., having a Gibbs free energy of formation per mole of oxygen gas below -400 kJ/mol), where the oxide formed using the conductive metal has a low bulk resistivity (e.g., having a bulk resistivity of less than approximately 0.5 kΩ-µm). A bulk resistivity higher than 0.5 kΩ-µm results in the resistance of the oxide to be formed hereafter (see FIG. 13) unnecessarily reducing the current density of the device, lowering overall performance of the transistor.

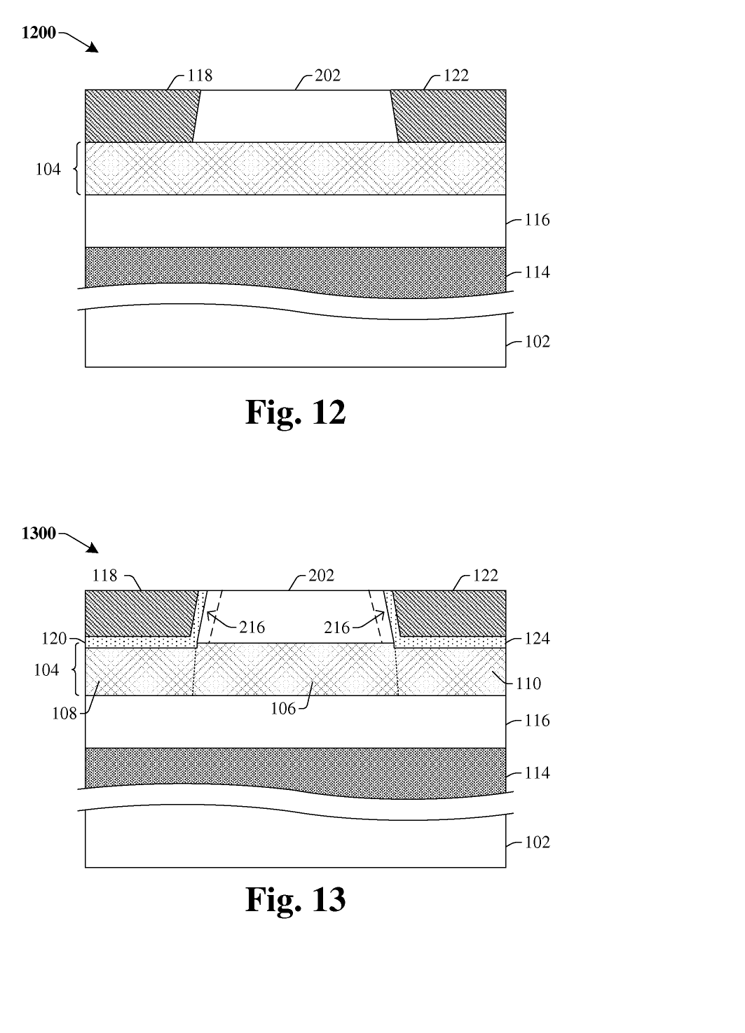

As shown in the cross-sectional view 1200 of FIG. 12, a portion of the conformal metal layer (see 1102 of FIG. 11) above an upper surface of the insulative layer 202 is removed, resulting in the first source/drain terminal 118 and the second source/drain terminal 122 remaining on the semiconductor layer 104. The portion of the conformal metal layer (see 1102 of FIG. 11) is removed using a planarization process (e.g., a chemical-mechanical planarization process). The first source/drain terminal 118 and the second source/drain terminal 122 are separated by the insulative layer 202.

As shown in the cross-sectional view 1300 of FIG. 13, an anneal is performed, resulting in the first and second oxide layers 120, 124 forming along the lower surfaces and outer sidewalls of the first and second source/drain terminals 118, 122. In some embodiments, the anneal comprises a heating the structure to a temperature between 250 and 300 degrees Celsius in a nitrogen gas environment. In some embodiments, the anneal has a duration between approximately 1 minute and 60 minutes, between approximately 5 minutes and 50 minutes, between approximately 3 minutes and 70 minutes, or another similar range. The first and second oxide layers 120, 124 comprise materials from the first and second source/drain terminals 118, 122, respectively, the semiconductor layer 104, and the insulative layer 202. That is, the first oxide layer 120 comprises materials form the first source/drain terminal 118 and the semiconductor layer 104, while the second oxide layer 124 comprises materials from the second source/drain terminal 122 and the semiconductor layer 104.

In some embodiments, the first and second oxide layers 120, 124 have thicknesses between approximately bnanometers and 5 nanometers, between approximately 2.5 nanometer and 4 nanometers, between approximately 3 nanometers and 6 nanometers, or within another, similar range. The thickness of the first and second oxide layers 120, 124 corresponds to the amount of oxygen sequestered from the semiconductor layer 104. Therefore, a thickness lower than the provided ranges indicates a low amount of oxygen has been removed from the semiconductor layer 104, resulting in a transistor that maintains a higher contact resistance.

The first and second oxide layers 120, 124 comprise a combination of the conductive metal of the first and second source/drain terminals 118, 122 and oxygen. For example, the first and second oxide layers 120, 124, are or comprise one or more of tantalum oxynitride, tantalum oxide (Ta₂O₅), titanium oxide, ruthenium oxide (RuO₂), a combination of the foregoing, or a material with a low bulk resistivity (e.g., a bulk resistivity of less than 0.5 kΩ-µm) formed from a conductive metal with a low oxide formation energy (e.g., having a Gibbs free energy of formation per mole of oxygen gas below -400 kJ/mol). The oxygen is pulled from the semiconductor layer 104 into the first and second oxide layers 120, 124. In some embodiments, the oxygen content of the first and second oxide layers 120, 124 varies across the thickness of the first and second oxide layers 120, 124. For example, the oxygen content of the first oxide layer 120 changes over a gradient between the first edge and the second edge, where the first edge is closer to the insulative layer 202 and the second edge is closer to the first source/drain terminal 118. Further, the oxygen content of the second oxide layer 124 changes over a gradient between the first edge and the second edge, where the first edge is closer to the semiconductor layer 104 and the second edge is closer to the second source/drain terminal 122.

The anneal further results in the first and second source/drain regions 108, 110 having a higher concentration of oxygen vacancies than the channel 106 due to the formation of the first and second oxide layers 120, 124. In some embodiments, the concentration of oxygen vacancies in the first and second source/drain regions 108, 110 is greater than 50%, while the concentration of oxygen vacancies in the channel 106 is less than 40%. The increased concentration of oxygen vacancies in the first and second source/drain regions 108, 110 results in a reduction in the contact resistance between the first and second source/drain regions 108, 110 and the first and second oxide layers 120, 124. The anneal further results in oxygen vacancy regions 216 being formed in the insulative layer 202 lining outer sidewalls of the first and second oxide layers 120, 124.

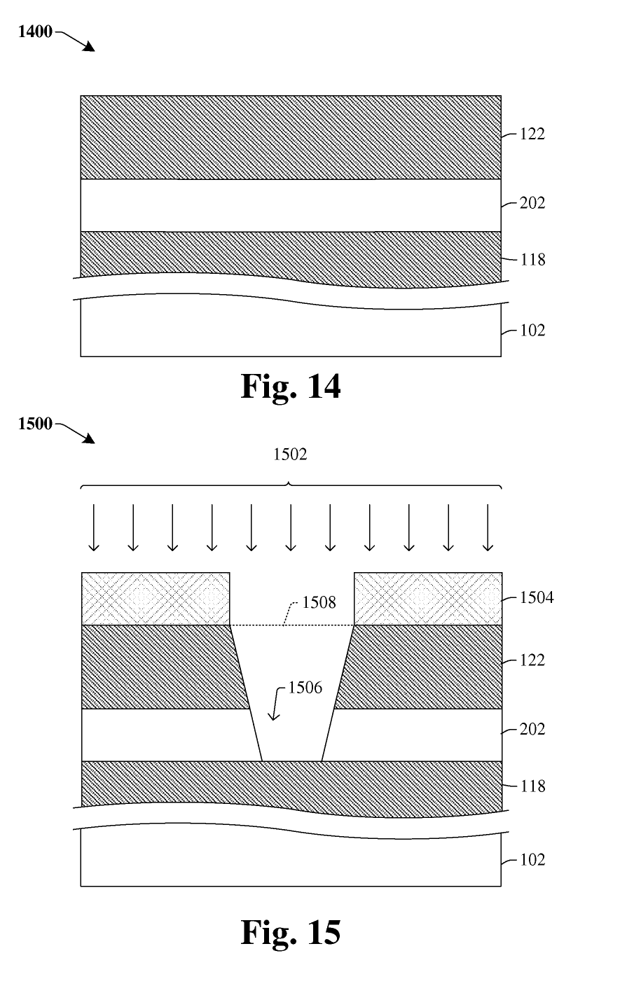

FIGS. 14-20 illustrate a series of cross-sectional views of some embodiments of a method of forming a transistor comprising a varying concentration of oxygen vacancies throughout a semiconductor layer with a gate stack extending between inner sidewalls of the first source/drain terminal towards the second source/drain terminal.

As shown in the cross-sectional view 1400 of FIG. 14, the first source/drain terminal 118 and the second source/drain terminal 122 are formed over the substrate 102. The insulative layer 202 is formed between forming the first source/drain terminal 118 and forming the second source/drain terminal 122. The first source/drain terminal 118, the insulative layer 202, and the second source/drain terminal 122 are independently formed using one or more of PVD, ALD, CVD, or the like.

As shown in the cross-sectional view 1500 of FIG. 15, a second masking layer 1504 is formed on the second source/drain terminal 122. In some embodiments, the second masking layer bis or comprises a photoresist and is patterned using photolithography. The second masking layer 1504 is formed using one or more of PVD, ALD, CVD, a spin on process, a dipping process, or the like. After the second masking layer 1504 is formed and patterned, a second etch 1502 is performed on the second source/drain terminal 122 and the insulative layer 202. In some embodiments, the second etch 1502 is an anisotropic dry etching process. The second etch 1502 results an opening 1506 extending through the second source/drain terminal 122 and the insulative layer 202 and exposing the first source/drain terminal 118. The second masking layer 1504 is then removed. In some embodiments, the opening 1506 is circular and has a diameter 1508 at its widest point between approximately 30 nanometers to 80 nanometers, approximately 50 nanometers to 100 nanometers, approximately 30 to 100 nanometers, or the like. In other embodiments, the opening 1506 is square, hexagonal, or another shape with a width at its widest point between approximately 30 nanometers to 80 nanometers, approximately 50 nanometers to 100 nanometers, approximately 30 to 100 nanometers, or the like.

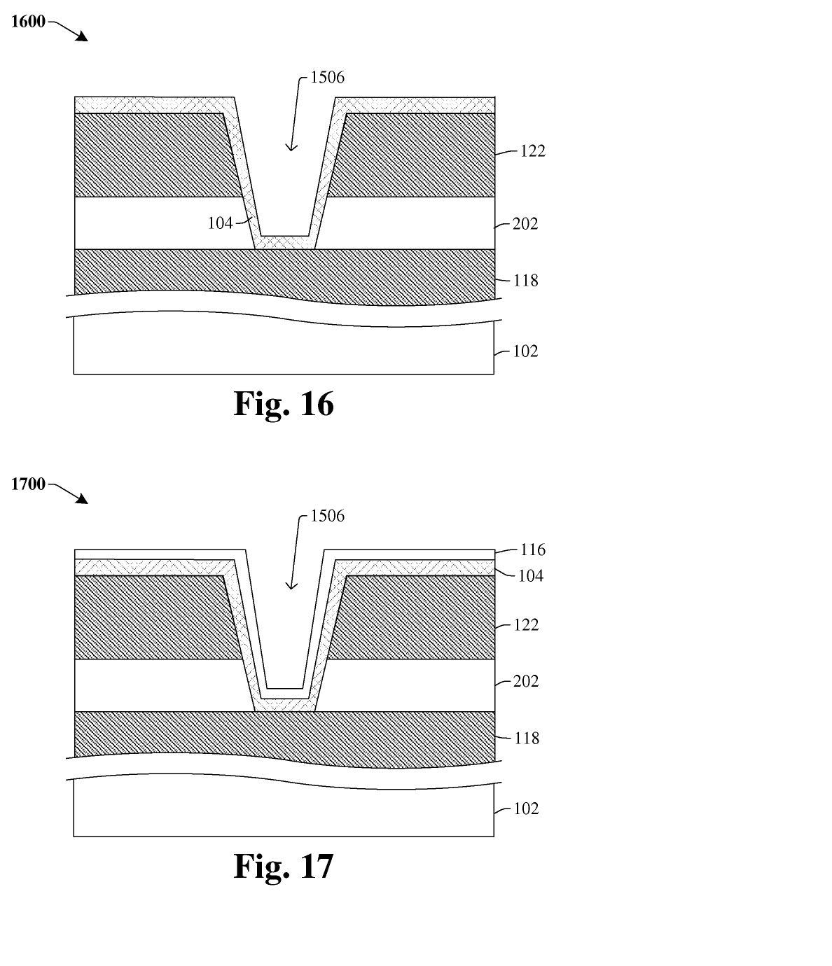

As shown in the cross-sectional view 1600 of FIG. 16, the semiconductor layer 104 is formed over the second source/drain terminal 122. The semiconductor layer 104 lines the opening 1506, covering inner sidewalls of the second source/drain terminal 122 and the insulative layer 202. In some embodiments, the semiconductor layer 104 is formed using one or more of PVD, ALD, CVD, or the like. In some embodiments, the semiconductor layer 104 is or comprises an oxide semiconductor material, such as indium gallium zinc oxide (IGZO), indium tungsten oxide (IWO), indium oxide (In₂O₃), indium tin oxide (ITO), zinc oxide (ZnO), tin oxide (SnO₂), nickel oxide (NiO), copper oxide (Cu₂O), or the like.

As shown in the cross-sectional view 1700 of FIG. 17, the gate dielectric 116 is formed over the semiconductor layer 104. The gate dielectric 116 lines the opening 1506, covering inner sidewalls and a lowest upper surface of the semiconductor layer 104. In some embodiments, the gate dielectric 116 is formed using one or more of PVD, ALD, CVD, or the like.

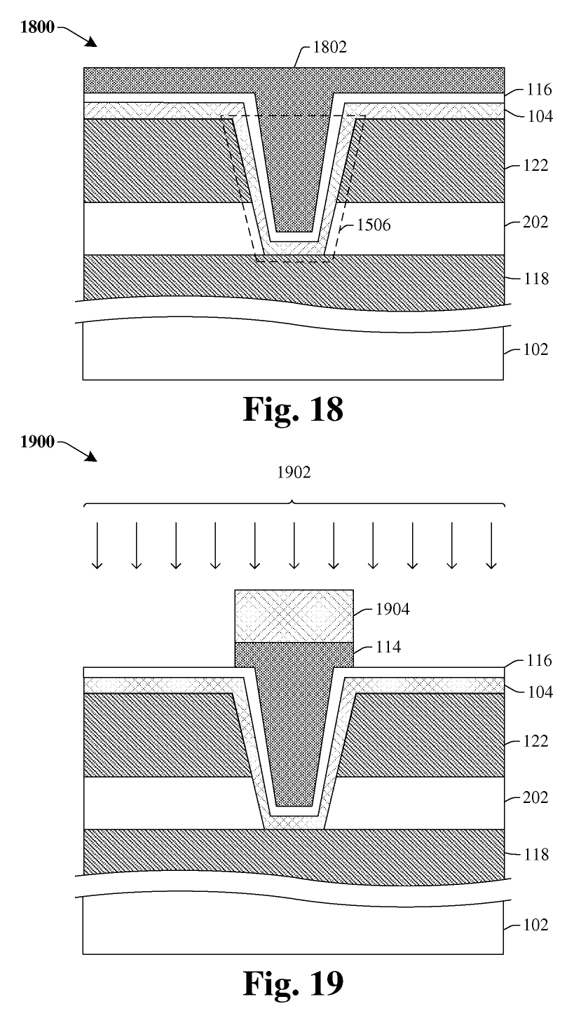

As shown in the cross-sectional view 1800 of FIG. 18, a second conformal metal layer 1802 is formed over the gate dielectric 116. The second conformal metal layer 1802 fills the opening 1506, covering inner sidewalls and a lowest upper surface of the gate dielectric 116. In some embodiments, the second conformal metal layer 1802 is formed using one or more of PVD, ALD, CVD, or the like.

As shown in the cross-sectional view 1900 of FIG. 19, a third masking layer 1904 is formed on the second conformal metal layer (see 1802 of FIG. 19). In some embodiments, the third masking layer 1904 is or comprises a photoresist and is patterned using photolithography. The third masking layer 1904 is formed using one or more of PVD, ALD, CVD, a spin on process, a dipping process, or the like. After the third masking layer 1904 is formed and patterned, a third etch 1902 is performed on the second conformal metal layer (see 1802 of FIG. 19). In some embodiments, the third etch 1902 is an anisotropic dry etching process. The third etch 1902 results in portions of the second conformal metal layer (see 1802 of FIG. 19) being removed, leaving the gate terminal 114 remaining over the substrate 102. The third masking layer 1904 is then removed.

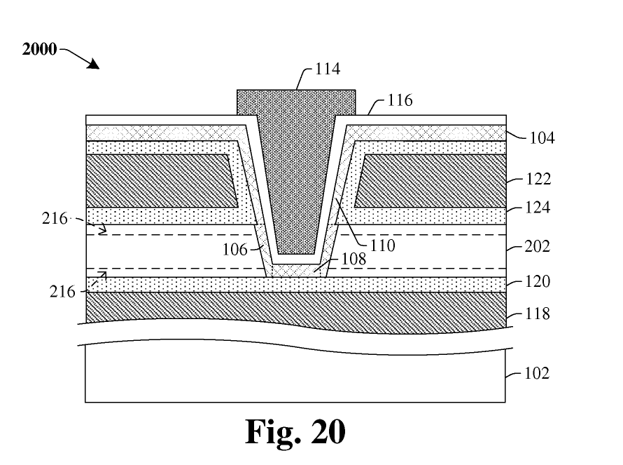

As shown in the cross-sectional view 2000 of FIG. 20, an anneal is performed, resulting in the first and second oxide layers 120, 124 forming along the surfaces and sidewalls of the first and second source/drain terminals 118, 122. In some embodiments, the anneal comprises a heating the structure to a temperature between 250 and 300 degrees Celsius in a nitrogen gas environment. In some embodiments, the anneal has a duration between approximately 1 minute and 60 minutes, between approximately 5 minutes and 50 minutes, between approximately 3 minutes and 70 minutes, or another similar range. The first and second oxide layers 120, 124 comprise materials from the first and second source/drain terminals 118, 122, respectively, the semiconductor layer 104, and/or the insulative layer 202. That is, the first oxide layer 120 comprises materials form the first source/drain terminal 118 and the insulative layer 202, while the second oxide layer 124 comprises materials from the second source/drain terminal 122 and the semiconductor layer 104.

In some embodiments, the first and second oxide layers 120, 124 have thicknesses between approximately 3 nanometers and 5 nanometers, between approximately 2.5 nanometer and 4 nanometers, between approximately 3 nanometers and 6 nanometers, or within another, similar range. The thickness of the first and second oxide layers 120, 124 corresponds to the amount of oxygen sequestered from the semiconductor layer 104. Therefore, a thickness lower than the provided ranges indicates a low amount of oxygen has been removed from the semiconductor layer 104, resulting in a transistor that maintains a higher contact resistance.

The first and second oxide layers 120, 124 comprise a combination of the conductive metal of the first and second source/drain terminals 118, 122 and oxygen. For example, the first and second oxide layers 120, 124, are or comprise one or more of tantalum oxynitride, tantalum oxide (Ta₂O₅), titanium oxide, ruthenium oxide (RuO₂), a combination of the foregoing, or a material with a low bulk resistivity (e.g., a bulk resistivity of less than 0.5 kΩ-µm) formed from a conductive metal with a low oxide formation energy (e.g., having a Gibbs free energy of formation per mole of oxygen gas below -400 kJ/mol). The oxygen is pulled from the semiconductor layer 104 into the first and second oxide layers 120, 124. In some embodiments, the oxygen content of the first and second oxide layers 120, 124 varies across the thickness of the first and second oxide layers 120, 124. For example, the oxygen content of the first oxide layer 120 changes over a gradient between the first edge and the second edge, where the first edge is closer to the insulative layer 202 and the second edge is closer to the first source/drain terminal 118. Further, the oxygen content of the second oxide layer 124 changes over a gradient between the first edge and the second edge, where the first edge is closer to the semiconductor layer 104 and the second edge is closer to the second source/drain terminal 122.

The anneal further results in the first and second source/drain regions 108, 110 having a higher concentration of oxygen vacancies than the channel 106 due to the formation of the first and second oxide layers 120, 124. In some embodiments, the concentration of oxygen vacancies in the first and second source/drain regions 108, 110 is greater than 50%, while the concentration of oxygen vacancies in the channel 106 is less than 40%. The increased concentration of oxygen vacancies in the first and second source/drain regions 108, 110 results in a reduction in the contact resistance between the first and second source/drain regions 108, 110 and the first and second oxide layers 120, 124. The anneal further results in oxygen vacancy regions 216 being formed in the insulative layer 202 lining outer sidewalls of the first and second oxide layers 120, 124.

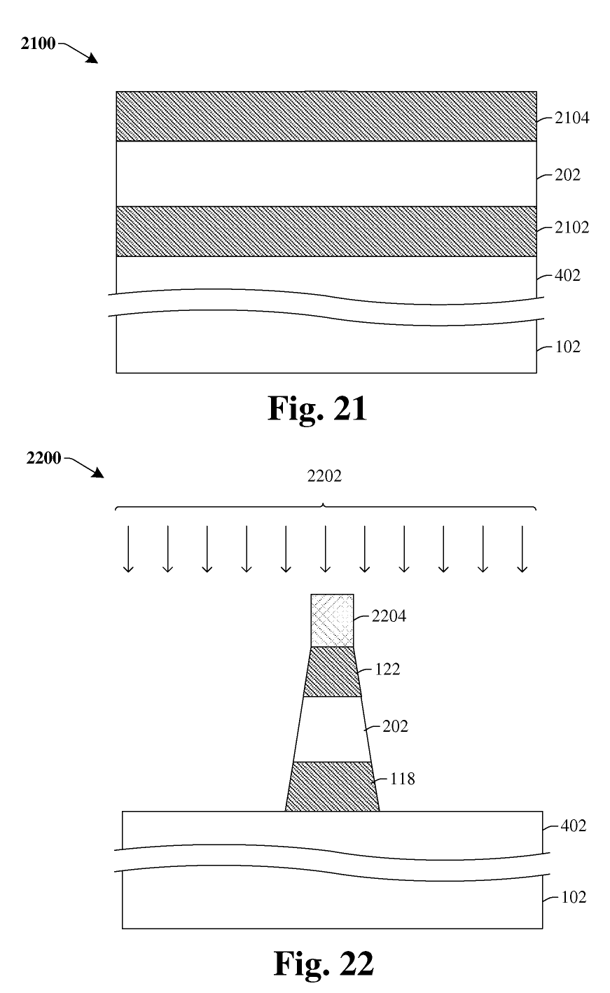

FIGS. 21-26 illustrate a series of cross-sectional views of some embodiments of a method of forming a transistor comprising a varying concentration of oxygen vacancies throughout a semiconductor layer with a gate stack extending around outer sidewalls of the first source/drain terminal and the second source/drain terminal.

As shown in the cross-sectional view 2100 of FIG. 21, the first metal layer 2102 and a second metal layer 2104 are formed over the substrate 102 and the second insulative layer 402. The insulative layer 202 is formed between forming the first metal layer 2102 and forming the second metal layer 2104. The first metal layer 2102, the insulative layer 202, and the second metal layer 2104 are independently formed using one or more of PVD, ALD, CVD, or the like.

As shown in the cross-sectional view 2200 of FIG. 22, a fourth masking layer 2204 is formed on the second metal layer (see 2104 of FIG. 21). In some embodiments, the fourth masking layer 2204 is or comprises a photoresist and is patterned using photolithography. The fourth masking layer 2204 is formed using one or more of PVD, ALD, CVD, a spin on process, a dipping process, or the like. After the fourth masking layer 2204 is formed and patterned, a fourth etch 2202 is performed on the second metal layer (see 2104 of FIG. 21), the insulative layer 202, and the first metal layer (see 2102 of FIG. 21). In some embodiments, the fourth etch 2202 is an anisotropic dry etching process. The fourth etch 2202 results in portions of the second metal layer (see 2104 of FIG. 21), the insulative layer 202, and the first metal layer (see 2102 of FIG. 21) being removed, exposing the second insulative layer 402 and delineating the first and second source/drain terminals 118, 122. The fourth masking layer 2204 is then removed.

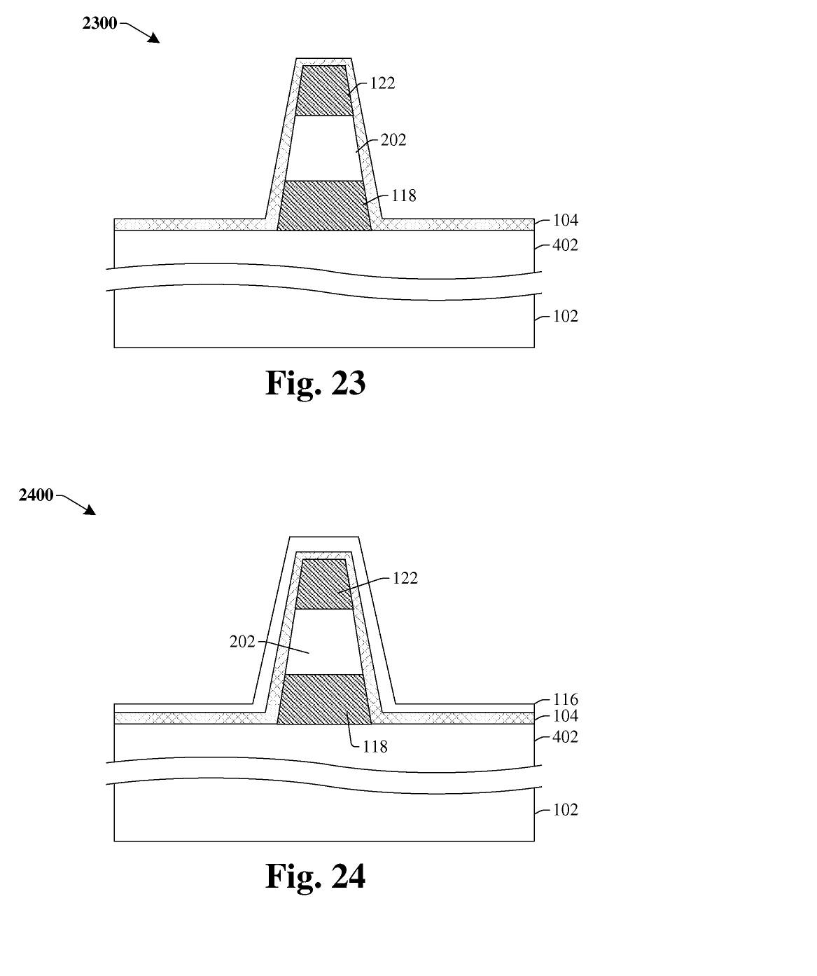

As shown in the cross-sectional view 2300 of FIG. 23, the semiconductor layer 104 is formed over the second insulative layer 402. The semiconductor layer 104 lines outer sidewalls of the second source/drain terminal 122, the insulative layer 202, and the first source/drain terminal 118. In some embodiments, the semiconductor layer 104 is formed using one or more of PVD, ALD, CVD, or the like. In some embodiments, the semiconductor layer 104 is or comprises an oxide semiconductor material, such as indium gallium zinc oxide (IGZO), indium tungsten oxide (IWO), indium oxide (In₂O₃), indium tin oxide (ITO), zinc oxide (ZnO), tin oxide (SnO₂), nickel oxide (NiO), copper oxide (Cu₂O), or the like.

As shown in the cross-sectional view 2400 of FIG. 24, the gate dielectric 116 is formed over the semiconductor layer 104. The gate dielectric 116 lines outer sidewalls and an uppermost surface of the semiconductor layer 104. In some embodiments, the gate dielectric 116 is formed using one or more of PVD, ALD, CVD, or the like. The semiconductor layer 104 separates the gate dielectric 116 from the second insulative layer 402.

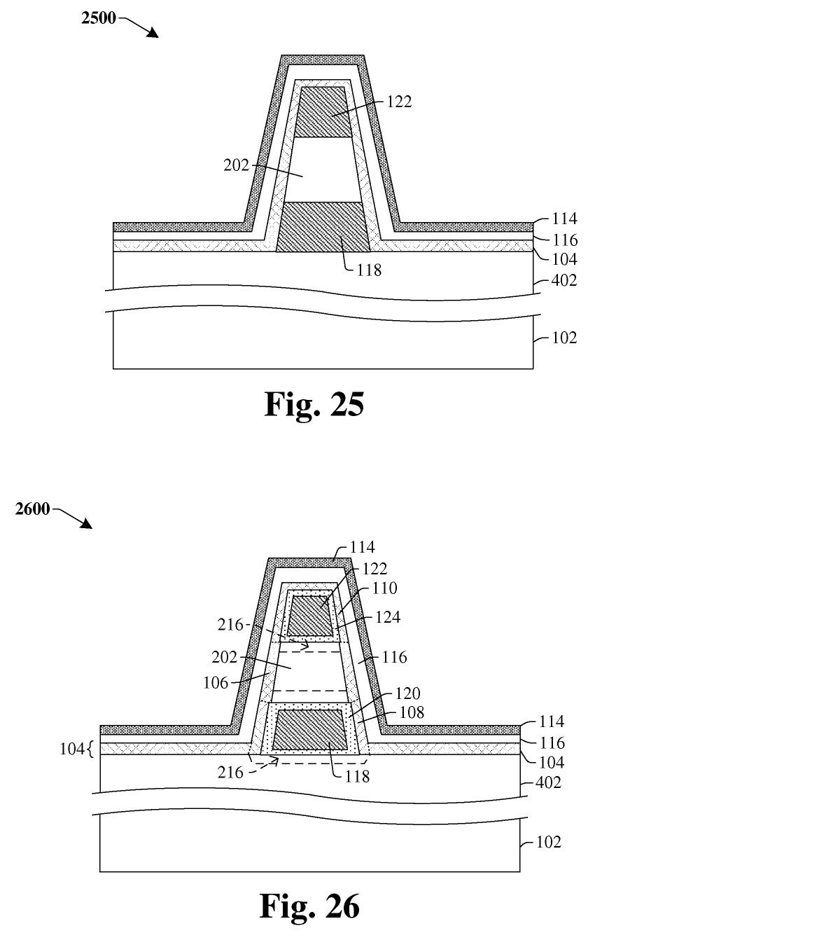

As shown in the cross-sectional view 2500 of FIG. 25, the gate terminal 114 is formed over the gate dielectric 116. The gate terminal 114 lines outer sidewalls and an uppermost surface of the gate dielectric 116, extending along outer sidewalls of the first source/drain terminal 118 and the second source/drain terminal 122. In some embodiments, the second conformal metal layer 1802 is formed using one or more of PVD, ALD, CVD, or the like.

As shown in the cross-sectional view 2600 of FIG. 26, an anneal is performed, resulting in the first and second oxide layers 120, 124 surrounding the first and second source/drain terminals 118, 122. In some embodiments, the anneal comprises a heating the structure to a temperature between 250 and 300 degrees Celsius in a nitrogen gas environment. In some embodiments, the anneal has a duration between approximately 1 minute and 60 minutes, between approximately 5 minutes and 50 minutes, between approximately 3 minutes and 70 minutes, or another similar range. The first and second oxide layers 120, 124 comprise materials from the first and second source/drain terminals 118, 122, respectively, the semiconductor layer 104, and the insulative layer 202. That is, the first oxide layer 120 comprises materials form the first source/drain terminal 118 and the semiconductor layer 104, while the second oxide layer 124 comprises materials from the second source/drain terminal 122 and the semiconductor layer 104.

In some embodiments, the first and second oxide layers 120, 124 have thicknesses between approximately 3 nanometers and 5 nanometers, between approximately 2.5 nanometer and 4 nanometers, between approximately 3 nanometers and 6 nanometers, or within another, similar range. The thickness of the first and second oxide layers 120, 124 corresponds to the amount of oxygen sequestered from the semiconductor layer 104. Therefore, a thickness lower than the provided ranges indicates a low amount of oxygen has been removed from the semiconductor layer 104, resulting in a transistor that maintains a higher contact resistance.

The first and second oxide layers 120, 124 comprise a combination of the conductive metal of the first and second source/drain terminals 118, 122 and oxygen. For example, the first and second oxide layers 120, 124, are or comprise one or more of tantalum oxynitride, tantalum oxide (Ta₂O₅), titanium oxide, ruthenium oxide (RuO₂), tungsten oxide (WO₂), a combination of the foregoing, or a material with a low bulk resistivity (e.g., a bulk resistivity of less than 0.5 kΩ-µm) formed from a conductive metal with a low oxide formation energy (e.g., having a Gibbs free energy of formation per mole of oxygen gas below -400 kJ/mol). The oxygen is pulled from the semiconductor layer 104 into the first and second oxide layers 120, 124. In some embodiments, the oxygen content of the first and second oxide layers 120, 124 varies across the thickness of the first and second oxide layers 120, 124. For example, the oxygen content of the first oxide layer 120 changes over a gradient between the first edge and the second edge, where the first edge is closer to the insulative layer 202 and the second edge is closer to the first source/drain terminal 118. Further, the oxygen content of the second oxide layer 124 changes over a gradient between the first edge and the second edge, where the first edge is closer to the semiconductor layer 104 and the second edge is closer to the second source/drain terminal 122.

The anneal further results in the first and second source/drain regions 108, 110 having a higher concentration of oxygen vacancies than the channel 106 due to the formation of the first and second oxide layers 120, 124. In some embodiments, the concentration of oxygen vacancies in the first and second source/drain regions 108, 110 is greater than 50%, while the concentration of oxygen vacancies in the channel 106 is less than 40%. The increased concentration of oxygen vacancies in the first and second source/drain regions 108, 110 results in a reduction in the contact resistance between the first and second source/drain regions 108, 110 and the first and second oxide layers 120, 124. The anneal further results in oxygen vacancy regions 216 being formed in the insulative layer 202 lining outer sidewalls of the first and second oxide layers 120, 124.

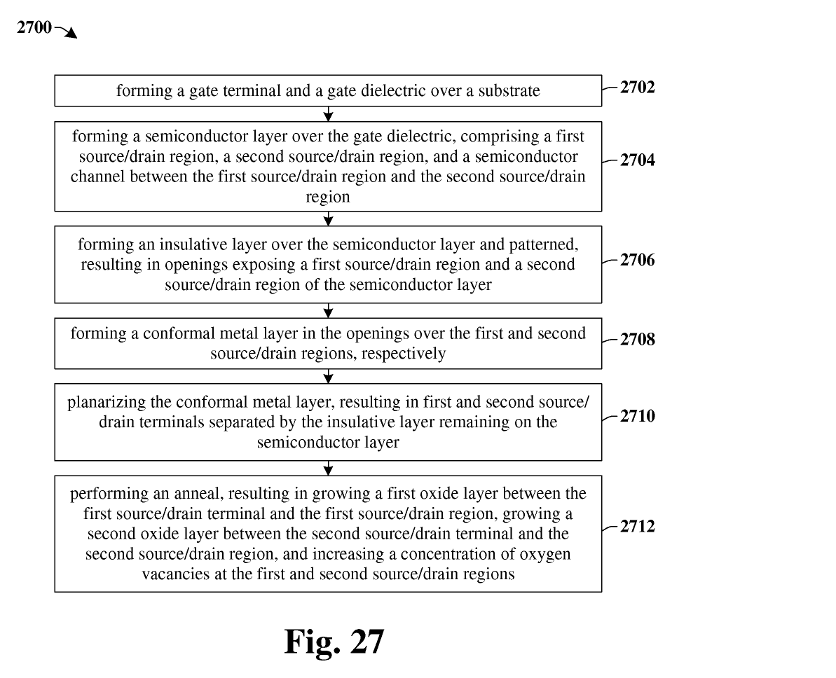

FIG. 27 illustrates a flowchart 2700 of some embodiments of a method of forming a transistor comprising a varying concentration of oxygen vacancies throughout a semiconductor layer with a gate stack beneath the semiconductor layer and the first and second source/drain terminals above the semiconductor layer. Although this method and other methods illustrated and/or described herein are illustrated as a series of acts or events, it will be appreciated that the present disclosure is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At 2702, a gate terminal and a gate dielectric are formed over a substrate. An example of a drawing illustrating this step can be found, for example, in FIGS. 6-7.

At 2704, a semiconductor layer is formed over the gate dielectric, the semiconductor layer comprising a first source/drain region, a second source/drain region, and a semiconductor channel between the first source/drain region and the second source/drain region. An example of a drawing illustrating this step can be found, for example, in FIGS. 8.

At 2706, an insulative layer is formed over the semiconductor layer and patterned, resulting in openings exposing a first source/drain region and a second source/drain region of the semiconductor layer. An example of a drawing illustrating this step can be found, for example, in FIGS. 9-10.

At 2708, a conformal metal layer is formed in the openings over the first and second source/drain regions, respectively. An example of a drawing illustrating this step can be found, for example, in FIG. 11.

At 2710, the conformal metal layer is planarized, resulting in first and second source/drain terminals separated by the insulative layer remaining on the semiconductor layer. An example of a drawing illustrating this step can be found, for example, in FIG. 12.

At 2712, an anneal is performed, growing a first oxide layer between the first source/drain terminal and the first source/drain region, growing a second oxide layer between the second source/drain terminal and the second source/drain region, and increasing a concentration of oxygen vacancies at the first and second source/drain regions. An example of a drawing illustrating this step can be found, for example, in FIG. 13.

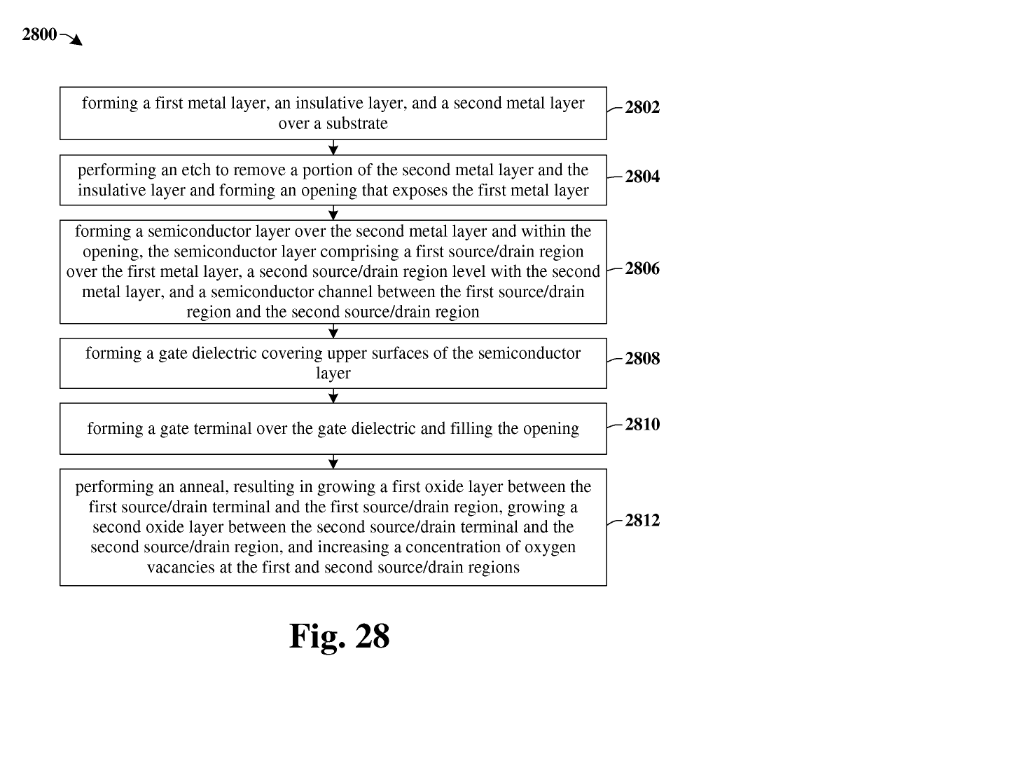

FIG. 28 illustrates a flowchart 2800 of some embodiments of a method of forming a transistor comprising a varying concentration of oxygen vacancies throughout a semiconductor layer with a gate stack extending between inner sidewalls of the first source/drain terminal towards the second source/drain terminal. Although this method and other methods illustrated and/or described herein are illustrated as a series of acts or events, it will be appreciated that the present disclosure is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At 2802, a first metal layer, an insulative layer, and a second metal layer are formed over a substrate. An example of a drawing illustrating this step can be found, for example, in FIG. 14.

At 2804, an etch is performed, removing a portion of the second metal layer and the insulative layer, forming an opening that exposes the first metal layer. An example of a drawing illustrating this step can be found, for example, in FIG. 15.

At 2806, a semiconductor layer is formed over the second metal layer and within the opening, the semiconductor layer comprising a first source/drain region over the first metal layer, a second source/drain region level with the second metal layer, and a semiconductor channel between the first source/drain region and the second source/drain region. An example of a drawing illustrating this step can be found, for example, in FIGS. 16.

At 2808, a gate dielectric is formed covering upper surfaces of the semiconductor layer. An example of a drawing illustrating this step can be found, for example, in FIG. 17.

At 2810, a gate terminal is formed over the gate dielectric and filling the opening. An example of a drawing illustrating this step can be found, for example, in FIGS. 18-19.

At 2812, an anneal is performed, growing a first oxide layer between the first source/drain terminal and the first source/drain region, growing a second oxide layer between the second source/drain terminal and the second source/drain region, and increasing a concentration of oxygen vacancies at the first and second source/drain regions. An example of a drawing illustrating this step can be found, for example, in FIG. 20.

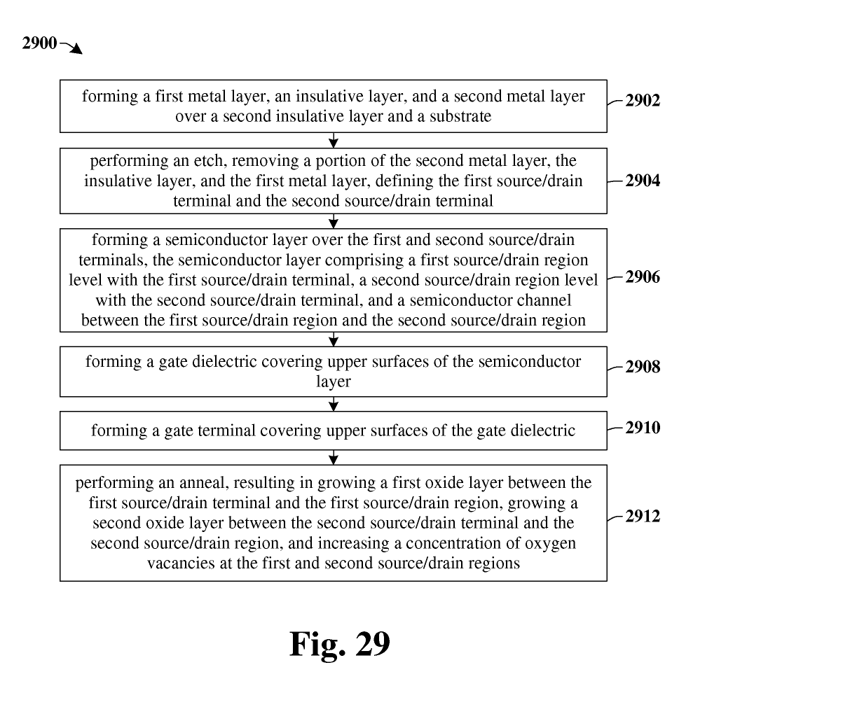

FIG. 29 illustrates a flowchart of some embodiments of a method of forming a transistor comprising a varying concentration of oxygen vacancies throughout a semiconductor layer with a gate stack extending around outer sidewalls of the first source/drain terminal and the second source/drain terminal. Although this method and other methods illustrated and/or described herein are illustrated as a series of acts or events, it will be appreciated that the present disclosure is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At 2902, a first metal layer, an insulative layer, and a second metal layer are formed over a second insulative layer and a substrate. An example of a drawing illustrating this step can be found, for example, in FIG. 21.

At 2904, an etch is performed, removing a portion of the second metal layer, the insulative layer, and the first metal layer, defining the first source/drain terminal and the second source/drain terminal. An example of a drawing illustrating this step can be found, for example, in FIG. 22.

At 2906, a semiconductor layer is formed over the first and second source/drain terminals, the semiconductor layer comprising a first source/drain region level with the first source/drain terminal, a second source/drain region level with the second source/drain terminal, and a semiconductor channel between the first source/drain region and the second source/drain region. An example of a drawing illustrating this step can be found, for example, in FIGS. 23.

At 2908, a gate dielectric is formed covering upper surfaces of the semiconductor layer. An example of a drawing illustrating this step can be found, for example, in FIG. 24.

At 2910, a gate terminal is formed covering upper surfaces of the gate dielectric. An example of a drawing illustrating this step can be found, for example, in FIGS. 25.

At 2912, an anneal is performed, growing a first oxide layer between the first source/drain terminal and the first source/drain region, growing a second oxide layer between the second source/drain terminal and the second source/drain region, and increasing a concentration of oxygen vacancies at the first and second source/drain regions. An example of a drawing illustrating this step can be found, for example, in FIG. 26.

Some embodiments relate to an integrated device, including: a semiconductor layer comprising a semiconductor channel; a gate on the semiconductor channel; a first source/drain region on a first side of the semiconductor channel; and a second source/drain region on a second side of the semiconductor channel opposite the first side; where the first source/drain region and the second source/drain region have a first concentration of oxygen vacancies, and the semiconductor channel has a second concentration of oxygen vacancies that is less than the first concentration of oxygen vacancies.

Other embodiments relate to an integrated device, including: a semiconductor layer comprising a semiconductor channel; a gate on the semiconductor channel; a first source/drain region on a first side of the semiconductor channel; a first source/drain terminal electrically coupled to the first source/drain region; a first oxide layer spacing the first source/drain terminal from the first source/drain region and comprising material from the first source/drain terminal and the first source/drain region; a second source/drain region on a second side of the semiconductor channel opposite the first side; a second source/drain terminal electrically coupled to the second source/drain region; and a second oxide layer spacing the second source/drain terminal from the second source/drain region, and comprising material from the second source/drain terminal and the second source/drain region.

Yet other embodiments relate to a method of forming an integrated device, including: forming a first metal layer over a substrate; forming a semiconductor layer over the first metal layer, comprising a first source/drain region, a second source/drain region, and a semiconductor channel between the first source/drain region and the second source/drain region; forming a second metal layer over the semiconductor layer; and performing an anneal, resulting in: growing of a first oxide layer where surfaces of the first metal layer or the second metal layer contact the first source/drain region, the first oxide layer lining an interface between the first source/drain region and the first metal layer or the second metal layer, wherein the first oxide layer comprises materials from the first source/drain region and materials from the first metal layer or the second metal layer; and growing a second oxide layer where surfaces of the first metal layer or the second metal layer contact the second source/drain region the second oxide layer lining an interface between the second source/drain region and the first metal layer or the second metal layer, wherein the second oxide layer comprises materials from the second source/drain regions and materials from the first metal layer or the second metal layer.

It will be appreciated that in this written description, as well as in the claims below, the terms “first”, “second”, “second”, “third” etc. are merely generic identifiers used for ease of description to distinguish between different elements of a figure or a series of figures. In and of themselves, these terms do not imply any temporal ordering or structural proximity for these elements, and are not intended to be descriptive of corresponding elements in different illustrated embodiments and/or un-illustrated embodiments. For example, “a first dielectric layer” described in connection with a first figure may not necessarily correspond to a “first dielectric layer” described in connection with another figure, and may not necessarily correspond to a “first dielectric layer” in an un-illustrated embodiment.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated device, comprising:
a semiconductor layer comprising a semiconductor channel;
a gate on the semiconductor channel;
a first source/drain region on a first side of the semiconductor channel; and
a second source/drain region on a second side of the semiconductor channel opposite the first side;
wherein the first source/drain region and the second source/drain region have a first concentration of oxygen vacancies, and the semiconductor channel has a second concentration of oxygen vacancies that is less than the first concentration of oxygen vacancies.

2. The integrated device of claim 1, further comprising:
a first source/drain terminal electrically coupled to the first source/drain region;
a first oxide layer spacing the first source/drain terminal from the first source/drain region;
a second source/drain terminal electrically coupled to the second source/drain region; and
a second oxide layer spacing the second source/drain terminal from the second source/drain region.

3. The integrated device of claim 2, further comprising a gate dielectric on a third side of the semiconductor channel, wherein the first source/drain terminal and the second source/drain terminal are on a fourth side of the semiconductor channel opposite the third side.

4. The integrated device of claim 2, wherein the first oxide layer and the second oxide layer extend into the semiconductor layer and have a bulk resistivity of less than 0.5 kΩ-µm.

5. The integrated device of claim 1, wherein the first concentration of oxygen vacancies is greater than 50%, and the second concentration of oxygen vacancies is less than 40%.

6. The integrated device of claim 1, wherein the first source/drain region extends from between inner sidewalls of the second source/drain region to outer sidewalls of the gate.

7. An integrated device, comprising:
a semiconductor layer comprising a semiconductor channel;
a gate on the semiconductor channel;
a first source/drain region on a first side of the semiconductor channel;
a first source/drain terminal electrically coupled to the first source/drain region;
a first oxide layer spacing the first source/drain terminal from the first source/drain region and comprising material from the first source/drain terminal and the first source/drain region;
a second source/drain region on a second side of the semiconductor channel opposite the first side;
a second source/drain terminal electrically coupled to the second source/drain region; and
a second oxide layer spacing the second source/drain terminal from the second source/drain region, and comprising material from the second source/drain terminal and the second source/drain region.

8. The integrated device of claim 7, wherein a first portion of the semiconductor layer directly beneath the first source/drain terminal and a second portion of the semiconductor layer directly beneath the second source/drain terminal have a first concentration of oxygen vacancies;
wherein the semiconductor channel has a second concentration of oxygen vacancies; and
wherein the first concentration is greater than the second concentration.

9. The integrated device of claim 7, further comprising an insulative layer extending directly between the first source/drain terminal and the second source/drain terminal;
wherein the first oxide layer separates the insulative layer and the first source/drain terminal; and
wherein the second oxide layer separates the insulative layer from the second source/drain terminal.

10. The integrated device of claim 9, wherein outer regions of the insulative layer have a third concentration of oxygen vacancies, and inner regions of the insulative layer have a fourth concentration of oxygen vacancies which is less than the third concentration of oxygen vacancies.

11. The integrated device of claim 7, wherein the semiconductor layer comprises inner sidewalls surrounding and level with the first source/drain terminal and the second source/drain terminal, and wherein the first source/drain terminal is directly above the second source/drain terminal.

12. The integrated device of claim 7, wherein the semiconductor layer extends from above the first source/drain region to an upper surface of the second oxide layer, and wherein the first source/drain terminal has an inner sidewall forming a continuous ring around the semiconductor channel and the first source/drain region.

13. A method of forming an integrated device, comprising:
forming a first metal layer over a substrate;
forming a semiconductor layer over the first metal layer, comprising a first source/drain region, a second source/drain region, and a semiconductor channel between the first source/drain region and the second source/drain region;
forming a second metal layer over the semiconductor layer; and
performing an anneal, resulting in:
growing of a first oxide layer where surfaces of the first metal layer or the second metal layer contact the first source/drain region, the first oxide layer lining an interface between the first source/drain region and the first metal layer or the second metal layer, wherein the first oxide layer comprises materials from the first source/drain region and materials from the first metal layer or the second metal layer; and
growing a second oxide layer where surfaces of the first metal layer or the second metal layer contact the second source/drain region the second oxide layer lining an interface between the second source/drain region and the first metal layer or the second metal layer, wherein the second oxide layer comprises materials from the second source/drain regions and materials from the first metal layer or the second metal layer.

14. The method of claim 13, wherein the anneal further results in a first concentration of oxygen vacancies in the first and second source/drain region, wherein the semiconductor channel has a second concentration of oxygen vacancies that is less than the first concentration of oxygen vacancies.

15. The method of claim 13, wherein the anneal is at a temperature of 200 to 350 degrees Celsius and occurs in an environment comprising nitrogen gas.

16. The method of claim 13, further comprising:
forming a first insulative layer before forming the semiconductor layer;
forming a third metal layer before forming the semiconductor layer and after forming the first insulative layer; and
etching the third metal layer and the first insulative layer to form openings in the third metal layer and the first insulative layer before forming the semiconductor layer;
wherein the semiconductor layer is formed within the openings.

17. The method of claim 16, further comprising forming a second insulative layer over the semiconductor layer before forming the second metal layer, wherein the second insulative layer separates the second metal layer from the semiconductor layer.

18. The method of claim 16, wherein the etching further etches the first metal layer, resulting in the openings extending to a bottom surface of the first metal layer.

19. The method of claim 13, further comprising:
forming a first insulative layer before forming the semiconductor layer;
forming a second insulative layer after forming the semiconductor layer;
patterning the second insulative layer to cover the semiconductor channel and leave exposed the first and second source/drain region;
wherein, after forming the second metal layer, the second metal layer covers the first and second source/drain region; and
performing a planarization process to remove portions of the second metal layer above an upper surface of the second insulative layer, resulting in forming first and second source/drain terminals over the first and second source/drain regions, respectively.

20. The method of claim 19, wherein the anneal further results in the first oxide layer and the second oxide layer forming along interfaces between the first and second source/drain terminals and the second insulative layer.
